(19) United States
(12) Patent Application Publication
(10) Pub. No.: US 2020/0006367 A1
(43) Pub. Date: Jan. 2, 2020

(54) 3D-Stacked Module with Unlimited Scalable Memory Architecture for Very High Bandwidth and Very High Capacity Data Processing Devices

(71) Applicant: Irvine Sensors Corporation, Costa Mesa, CA (US)

(72) Inventors: Christian Krutzik, Costa Mesa, CA (US); James Yamaguchi, Laguna Niguel, CA (US); Samba He, Riverside, CA (US)

(73) Assignee: Irvine Sensors Corporation, Costa Mesa, CA (US)

(21) Appl. No.: 16/407,466

(22) Filed: May 9, 2019

Related U.S. Application Data
(60) Provisional application No. 62/668,933, filed on May 9, 2018.

(51) Int. Cl. H01L 27/11556; H01L 27/11582; G11C 5/06; H01L 23/495; H01L 25/065; G11C 16/06

(52) U.S. Cl. CPC H01L 27/11556; H01L 27/11582; G11C 5/06; G11C 16/06; H01L 23/49541; H01L 23/49575; H01L 25/0657; H01L 23/49517

(57) ABSTRACT

A 3-D memory module comprising a plurality of packaged integrated memory circuits or devices is mounted to a substrate with integrated pins that are edge-connected on two surfaces where the top surface provides an edge connection from the integrated memory circuits to an orthogonally-mounted memory controller circuit through a wide-word interface. Each integrated memory device can be accessed independently wherein the memory controller is configured to reduce the wide-word interface to a serial interface which is brought to the opposite surface of the memory module for electrical coupling to an external system or printed circuit assembly.

### BACKGROUND OF THE INVENTION

### 1. Field of the Invention

The invention relates to the field of electronic memory devices. More specifically, the invention relates to a high capacity electronic memory module enabled by an unlimited scalable interconnect scheme. The invention comprises a flexible and unlimited scalable memory interconnect solution that provides very high memory capacities with distributed processing of the memory. For reference, very high memory capacities are contemplated as being on the order of 1,000 integrated circuit packages of state-of-the-art (SOTA) electronic memory devices.

### 2. Brief Description of the Prior Art

Current non-volatile memory technologies such as NAND flash generally use a point-to-point parallel interface requiring, for example, 13 input/output (I/O) lines per memory device. Interconnecting this form of memory device to achieve very high memory capacities and to produce an ideal and maximum achievable bandwidth requires a wide-word scheme that results in 1000×13 or 13,000 I/O which is not an achievable or practical I/O count for existing memory controllers.

Such a high capacity connection scheme requires bussing the numerous individual memory devices onto a common memory bus which immediately reduces available bandwidth since only one memory device can be accessed on the memory bus at a time. Additional states of the various memory devices can produce bus contention which reduces the effective bandwidth of the bus even further (e.g., the chip select (CS) setup and hold times add additional latency between accessing different devices).

Memory capacity is scalable using memory devices that are configured in parallel but this becomes problematic from an electrical and layout perspective for a large number of memory packages. In the electrical domain, parallel loading increases the bus load (i.e., capacitance) which in turn reduces the signal edge rates and increases required I/O power. The reduced edge rates reduce the available timing margin which in turn reduces interface speeds. This reduced interface speed is compounded when placing a large number of memory packages on a printed circuit board (PCB) as the physical footprint of the devices themselves further increases capacitance due to the separation between the memory controller and the individual memory elements. The aforementioned increased footprint also incurs other electrical penalties in the form of crosstalk, electromagnetic emissions and power supply noise.

As an example and not by way of limitation, take a large memory array which seeks to interconnect an exemplary 1,000 NAND devices at maximum bandwidth. A typical NAND flash is housed in an 18×12 mm package—assuming roughly a 1 mm additional space per memory device side being required for decoupling capacitors. In this example, supporting a discrete printed circuit board requires 20×14×1000 or 280,000 mm\hat{ }2 or 2,800 cm\hat{ }2 of printed circuit board surface area. This is roughly a 53 cm (21 in.)×53 cm (21 in.) circuit board for the memory elements alone, not including the controller, buffers, and other peripheral logic. In addition, such a circuit board would comprise 13×1,000 or 13,000 I/O lines, all requiring appropriate routing.

Current SOTA memory controller devices have maximum I/O counts of about 1,200 (e.g., Xilinx Virtex-6 FPGA) which entails using multiple controllers in the exemplar system. Because these memory controllers must also provide an external interface, only a subset of the provided I/O can be used for the memory devices themselves; a typical value might be 1,000 out of 1,200. Accordingly, the above example would require the use of 13 memory controller devices. A memory controller with such a high level of I/O would be roughly 42×42 mm in size and would require roughly an equivalent surface area for its support components. The memory controllers alone might occupy 13×42×42×2 or 450 cm\hat{ }2, bringing the total PCB real estate up to about 3,250 cm\hat{ }2. Typically, the memory controller is located at a PCB edge since the memory controller requires multi-gigabit transceivers (MGT)—i.e., placing the memory controller in the center of the printed circuit board puts stricter demands on the MGT.

Routing MGTs over 10 inches typically requires use of low-loss dielectrics which further increases cost. In this configuration, the signals to and from the NAND devices would need to be driven over 21 inches of PCB, typically an FR4 material (FR4 is a NEMA grade designation for glass-reinforced epoxy laminate material). At these lead lengths, RF emissions as well as crosstalk become serious considerations. Such a system design, although feasible, will run into multiple issues relative both to maintaining signal quality and power delivery network requirements which increases the printed circuit board size even further, e.g., requiring signal-to-signal spacing of (5)×trace width in order to acceptably reduce crosstalk below 2%.

From the illustrated example, it can be seen that expanding the example beyond 1,000 memory parts would require a completely new board design as additional memory controllers are required and additional signal integrity mitigation/design must be performed as trace lengths increase further.

In addition to high capacity data storage, the above performance concerns also pertain similarly to data processing where such issues are encountered and a high density memory solution is needed to address them.

### BRIEF DESCRIPTION OF THE SEVERAL VIEWS OF THE DRAWINGS

FIG. 1 depicts an exemplary group of daisy-chained modules in a triple modular redundancy configuration of the memory module of the disclosure.

FIG. 2A illustrates a side view of an exemplary memory module of the invention and FIG. 2B illustrates a memory module high level block diagram of the memory module of FIG. 2A.

FIG. 3 illustrates an exemplary block diagram of a circuit comprising a plurality of the memory modules of the disclosure.

FIG. 4 depicts an exemplary interconnect scheme of the memory module of the disclosure.

FIG. 5 depicts a plurality of T-connects of the memory module of the disclosure utilizing exposed cross sections of the internal lead frame of the IC package and electronically conductive connections.

FIG. 6 depicts a daisy chain configuration of a plurality of the memory module of the disclosure.

FIGS. 7A-7S depict an exemplary set of process steps for the fabrication of a memory module of the disclosure.

The disclosure and its various embodiments can now be better understood by turning to the following description of the preferred embodiments which are presented as illustrated examples of the invention in any subsequent claims in any application claiming priority to this application. It is expressly understood that the inventions as defined by such claims may be broader than the illustrated embodiments described below.

### DETAILED DESCRIPTION

Applicant discloses a device, system and method for making a three-dimensional memory module having a scalable interconnect architecture.

The instant disclosure addresses issues encountered with creating very high density and very high bandwidth memory devices using 3D packaging to reduce 2D board real estate and provides an unlimited scalable interconnect architecture (USIA) to simplify interconnectivity. The disclosure enables a means for achieving arbitrarily large memory capacities and user-defined word widths without the need for complex PCB routing and signal integrity concerns of prior art approaches. The disclosed USIA architecture also allows efficient daisy-chaining of memory module devices such that the interconnect length between individual memory devices is minimized.

These and various additional aspects, embodiments and advantages of the present disclosure will become immediately apparent to those of ordinary skill in the art upon review of the specification and the claims to follow.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

The invention is applicable to high capacity and high bandwidth data storage devices. It can be used in conjunction with any non-volatile or volatile memory technology such as DDR, NAND, MRAM, ReRAM, or SRAM. In the non-limiting examples in the specification, each memory module combines, but is not limited to, a stack of ten (10) memory device packages and a memory controller (which may comprise an FPGA or other processor device) within a footprint of roughly twice the size of a single memory device package (i.e., a 5× reduction in memory package spacing) but any user-defined number and combination of memory device packages and memory controllers are contemplated as falling within the scope of the specification and claims herein.

The associated memory controller reduces the wide-word interface from the individual memory devices in the memory module by means of multiple MGT I/O interfaces on the memory module, where there is both an “in” and “out” port to permit device daisy-chaining. Daisy-chaining permits the total memory capacity to be scaled without an impact on routing requirements due to the scaling (i.e., the design rules, methodology, board layer count, etc. remain the same).

The invention is also applicable to parallel data processing devices such as are used in artificial neural network-based computing or big-data mining applications. In such an implementation, each memory module may contain a dedicated processing node, such as an FPGA, processor, DSP, or GPU, that has immediate direct memory access to internal data in the memory devices. An exemplary application may be facial recognition from a very large data set. The invention provides a means for a main controller to distribute a task, such as neural network-based matching, to a distributed set of processing nodes where each processing node has direct access to a portion of the large data set in memory whereas the large data set would normally be randomly assigned to each node. In other words, the collection of memory devices acts as a single memory device. Processing at-the-data eliminates or minimizes typical bottlenecks and limitations of memory access storage devices that are separated by multiple levels of hardware and software abstraction.

In such an embodiment, each memory module calculates its best match with low latency, in parallel, and returns its result to the main controller. The main controller then simply compares results and extracts the best match from the results. A key enabler in this embodiment is that all calculations occur in parallel such that the scale or capacity of the memory array latency does not affect the performance, i.e., whether the dataset is 128 TB, 2048 TB, or larger, the calculation requires the same duration.

The memory module is comprised of a plurality of stacked memory devices which are electrically edge-connected to a dedicated memory controller that is orthogonally disposed on an upper lateral surface of the stack of memory devices to allow a wide-word interface to the individual memory devices in the stack in a direct, electrically optimum, manner. The memory controller is configured to reduce the wide-word interface into a MGT-based or high speed serial I/O interface which is then routed between, on or through the vertically stacked memory device layers on a reroute layer or printed wire assembly to the underlying PCB and external system. A parallel interface can be implemented in the memory module. The memory module may also contain all necessary high frequency bypass capacitors, further reducing printed circuit board real-estate.

The disclosed memory module desirably reduces needed printed circuit board surface area by stacking multiple memory devices. Further, the memory module improves board-level signal integrity when dealing with very high memory package counts by reducing the wide-word interface into a high speed serial interface using MGT without sacrificing bandwidth.

Yet further, the memory module improves board-level power network delivery when dealing with very high memory package counts by incorporating required high frequency bypass capacitors. The memory module may also contain point-of-load (POL) devices to further simplify power distribution by being more tolerant to main voltage rail ripple and noise. The point of load power regulation may comprise a voltage regulator in the memory module. The system board may have a 12V or 24V rail distributed through the power planes and then each memory module down converts it to necessary lower voltage. This is a standard method used when delivering large currents since it reduces performance requirements of the power plane where it's easier on the mechanical aspects to distribute large voltage than it is a large current (i.e. there is more tolerance to voltage droop, ripple, etc).

The MGT interfaces of the memory module can use industry-standard electrical interfaces using, for example, current-mode logic (CML). Furthermore, the USIA interface can leverage existing serial protocol such as Serial Rapid IO for memory module communication.

The USIA memory module of the invention simplifies the interconnects between different memory modules by providing a daisy-chainable interface that allows short, point-to-point serial interconnections regardless of memory module count. The memory module can be fabricated using conventional printed circuit board assembly and manufacturing technologies. The integrated pin-to-board interconnections provide a dual-function as they are also used during assembly for device and lead alignment.

Additionally, the invention allows n-sides, i.e., planar external surface areas of the memory module (one to six sides of the stack) of connectivity to a memory module for advanced data and signal routing within a memory module or a rack of memory modules. This can be accomplished by expanding on the invention described herein and attaching interface circuitry to each memory module lateral surface or face such that it can interface to an adjacent memory module. As adjacent memory modules may not be in electrical or physical contact, a signal interface using optical or other electro-magnetic medium may be used.

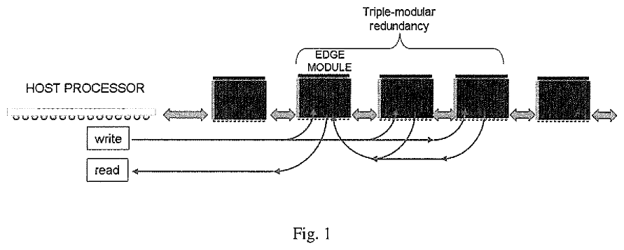

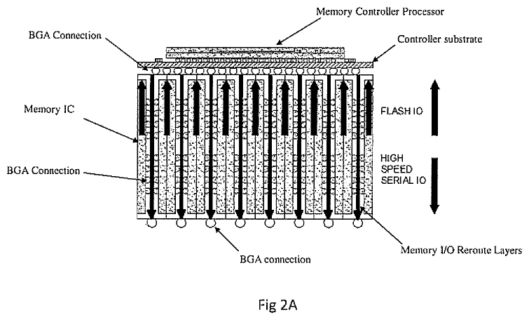

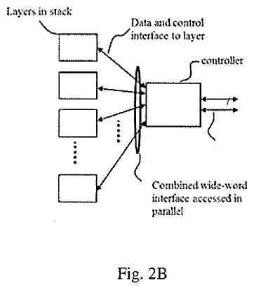

In a first aspect of the invention, as depicted in FIGS. 1 and 2A and 2B, a memory module comprising a plurality of packaged integrated memory circuits or devices is mounted to a substrate with integrated pins that are edge-connected on two lateral surfaces where the top surface provides an edge electrical connection from the integrated circuits to an orthogonally-mounted memory controller circuit through a wide-word interface. In this manner, each integrated memory device in the memory module can be accessed independently whereby the orthogonally mounted memory controller is configured to reduce the wide-word interface to a serial interface which is brought to the opposite surface of the memory module for electrical coupling to the system substrate or PCB.

In a second aspect of the invention, the substrate uses a lead frame that is soldered or welded to the substrate. Each finger of the lead frame is used for aligning the memory device layers to the required pitch to mount the memory controller as well as for providing a means for compliance and flexibility in achieving the device pitch.

In a third aspect of the invention, a method using the lead frame is disclosed wherein after a plurality of memory device packages are stacked and the lead frame fingers are bent in a J-lead fashion to provide a planar surface for mounting the memory controller circuit.

In a fourth aspect of the invention, a method using the lead frame is disclosed wherein after the plurality of memory device packages are stacked, the lead frame in cut or lapped planar with the edge surface such that the exposed cross section of the electrically conductive lead frame provides an electrically conductive contact or pad that can be used for ball-grid array type attachment for mounting the memory controller circuit.

In a fifth aspect of the invention, a method of communication is provided between memory modules in any direction independently to allow bypassing of routing signals out of the overall physical memory and back in.

In a sixth aspect of the invention, a method is disclosed for using an enclosure to channel communication via a waveguide (electrical, physical hollow waveguides, or optical) to create larger zones of memory for applications dealing with massive data sets and data distributed applications.

In a seventh aspect of the invention, a visual indicator is provided on a surface of the memory module and provides error or operational status of the memory module and its individual memory device components and to provide a means for identifying and replacing failed memory modules.

In an eighth aspect of the invention, the input/output interface of the memory module uses pins or leads that can be inserted into receptacles on the host substrate to allow the memory module to be easily replaced. The pins or leads may be designed with an enlarged size near the memory module so as to provide a standoff when inserted into the host substrate or connector to accommodate inspection.

In a ninth aspect of the invention, the receptacles have multiple contact surfaces such that removal of the memory module closes a mechanical circuit allowing the daisy-chainable signal path to remain active so that the modules can be hot-swapped or removed without affecting the signal chain connectivity.

In a tenth aspect of the invention, each daisy-chained serial interface of a group of memory modules contains a terminating circuit wherein each terminating circuit is connected to adjacent terminating circuits such that the terminating circuit can automatically connect the end of one serial chain to the end of another serial chain for the purpose of extending the serial chain in case of failure or breakage of one serial chain.

In an eleventh aspect of the invention, a point-of-load power regulation within the memory module is performed to simplify power distribution of the substrate. The point of load power regulation may comprise of a voltage regulator in the memory module. The system board may be provided with a, for example, 12V or 24V rail that is distributed through the power planes of the system and then each module down converts it to a lower voltage. This is a standard method used when delivering large currents since it reduces the performance requirements of the power plane where it's easier on the mechanical aspects to distribute large voltage than it is a large current (i.e., there is more tolerance to voltage droop, ripple, etc).

In a twelfth aspect of the invention, a subset of memory modules can be configured in a n-modular redundancy (nMR) fashion where the memory controller performs the required voting and redundancy operations relieving the host controller from any such duties. From the host controller perspective, the nMR operation may be transparent.

In a thirteenth aspect of the invention, a specific memory module within a set of memory modules can be configured as a parity module. The parity module stores the exclusive-or (XOR) of the set of memory modules such that a failed module can be rebuilt or reconstructed from the parity module. If the parity module is configured within a single chain, it may listen to all writes within the chain in a promiscuous mode such as not to require additional addressing by the host.

In a fourteenth aspect of the invention when used with NAND flash devices, the flash translation layer (FTL) is distributed between the host controller and the memory controller of each memory module such that the host controller requires only a subset of the FTL which would be proportional to the number of memory modules therewith improving performance of the host controller and minimizing address translation lookup table requirements.

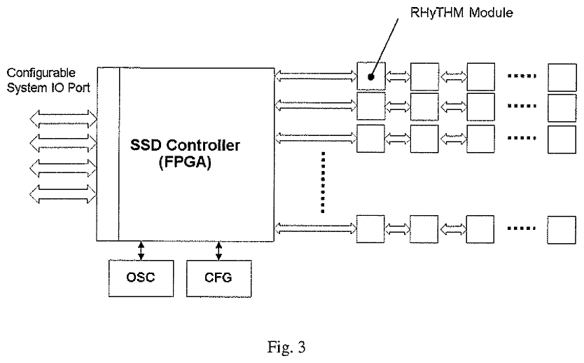

FIG. 3 illustrates an exemplary block diagram of a circuit comprising a plurality of the memory modules of the disclosure.

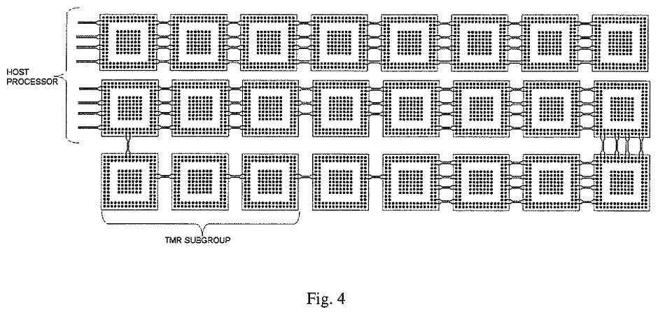

FIG. 4 depicts an exemplary interconnect scheme of a plurality of the memory modules of the disclosure.

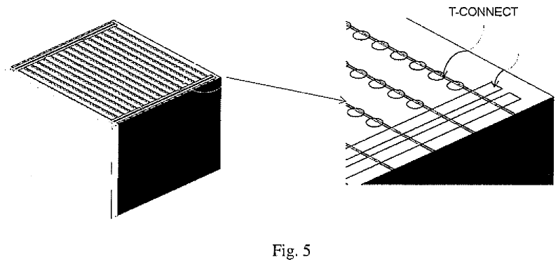

FIG. 5 depicts a plurality of T-connects on a lateral surface of the memory devices for accessing memory therein of the memory module of the disclosure.

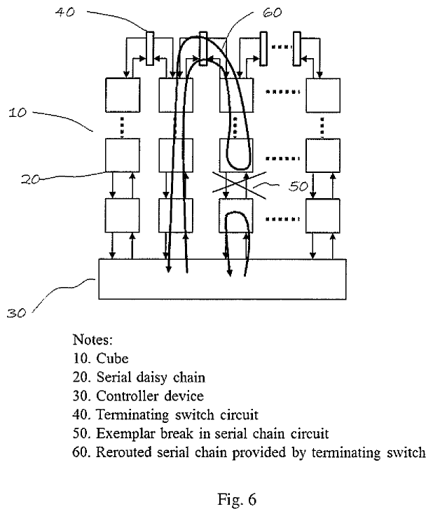

FIG. 6 depicts an exemplary daisy chain configuration of a plurality of the memory module of the disclosure.

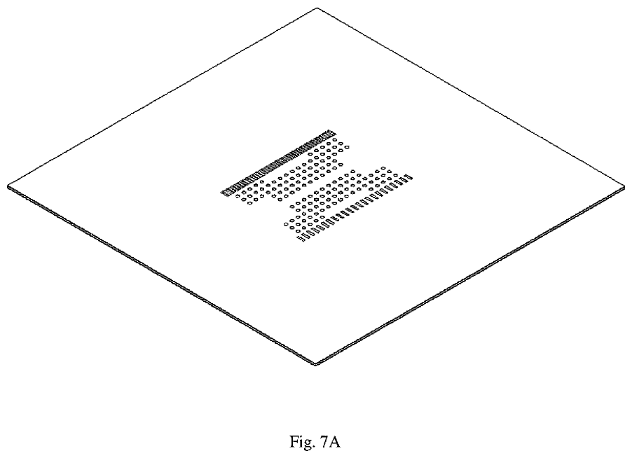

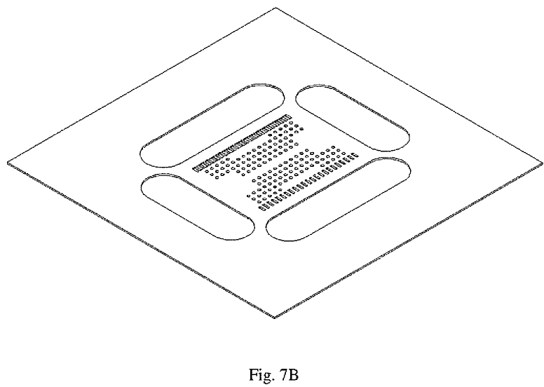

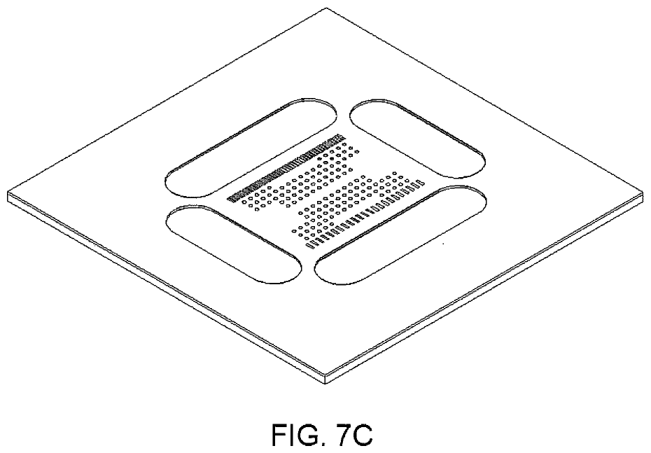

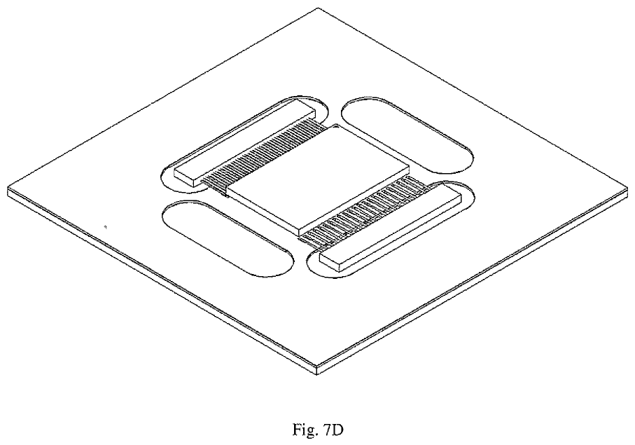

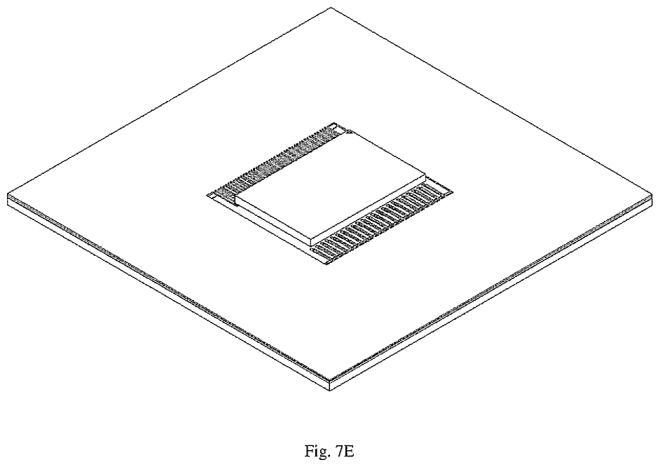

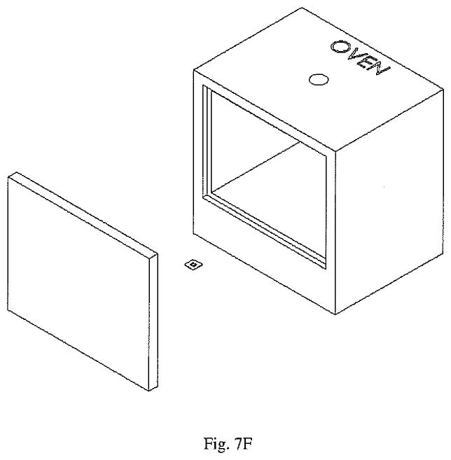

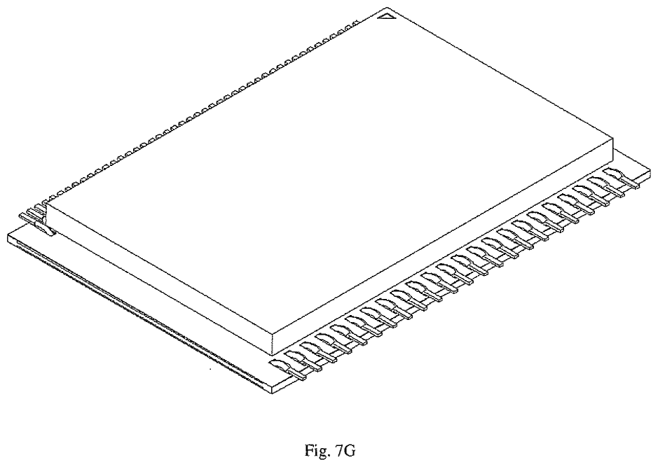

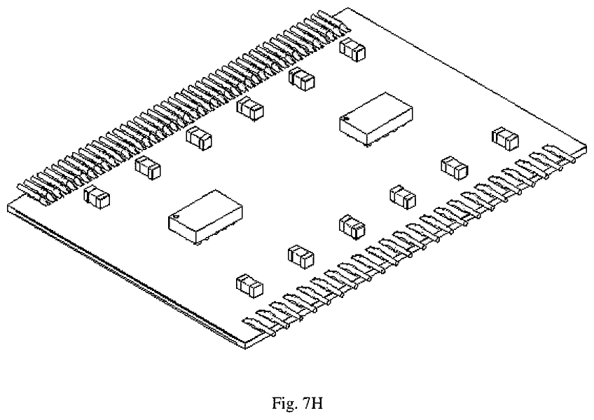

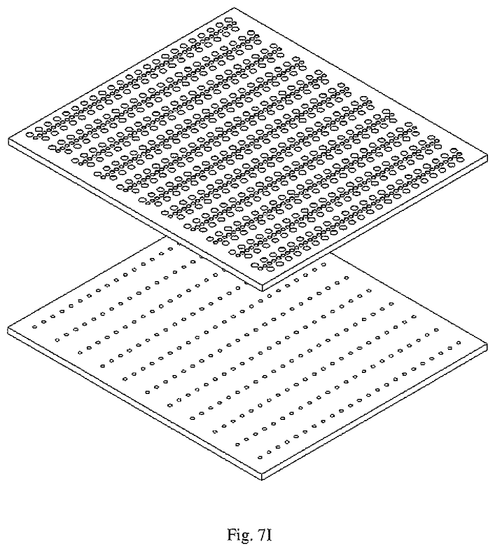

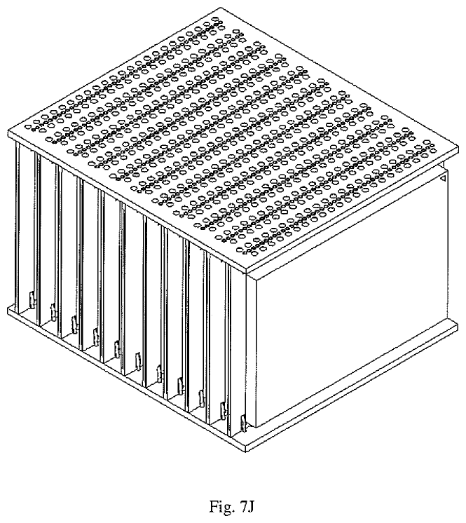

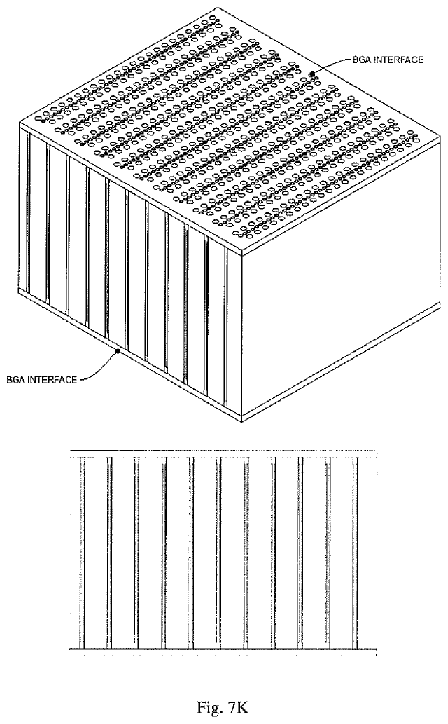

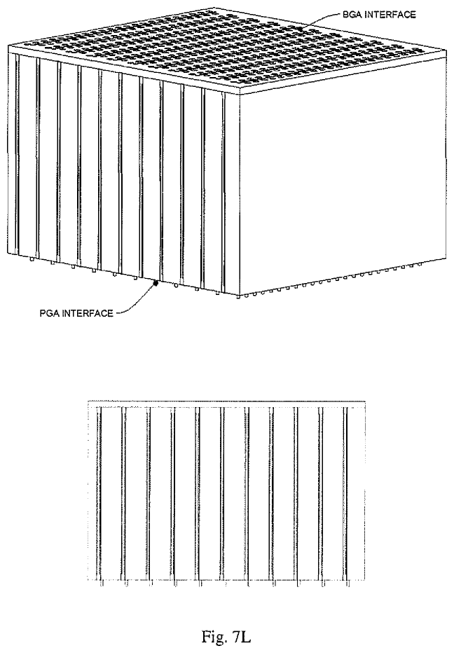

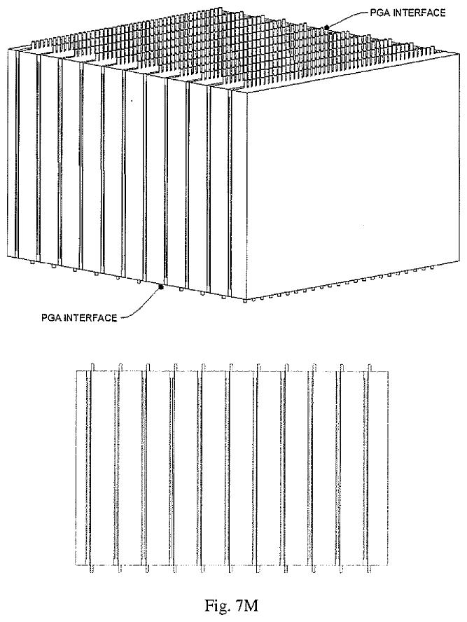

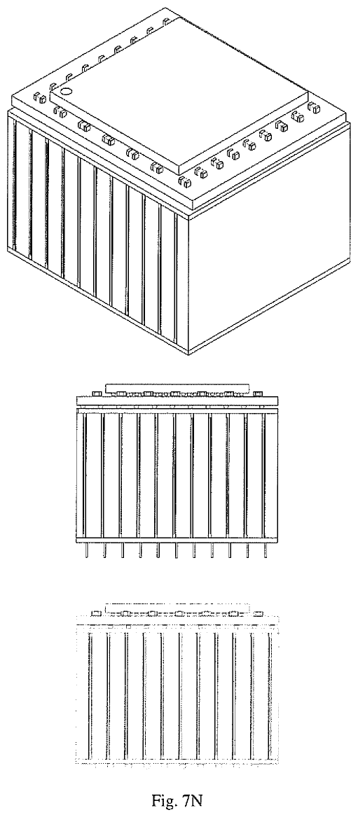

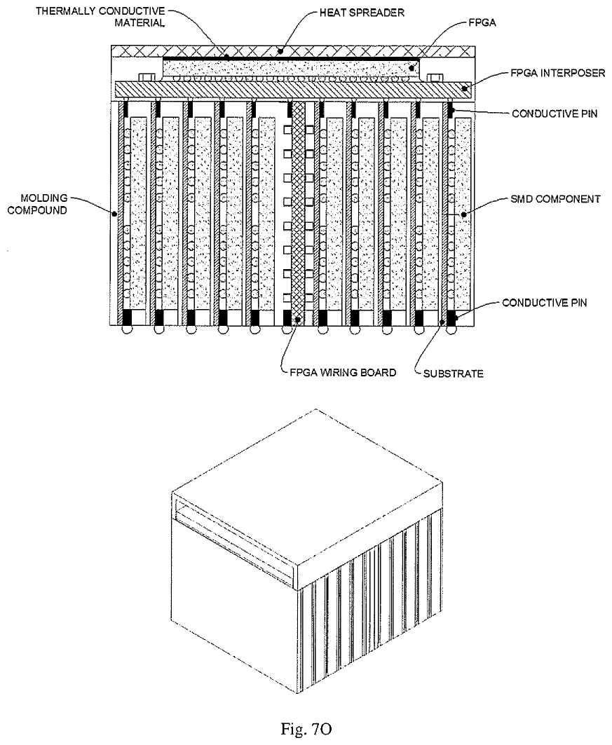

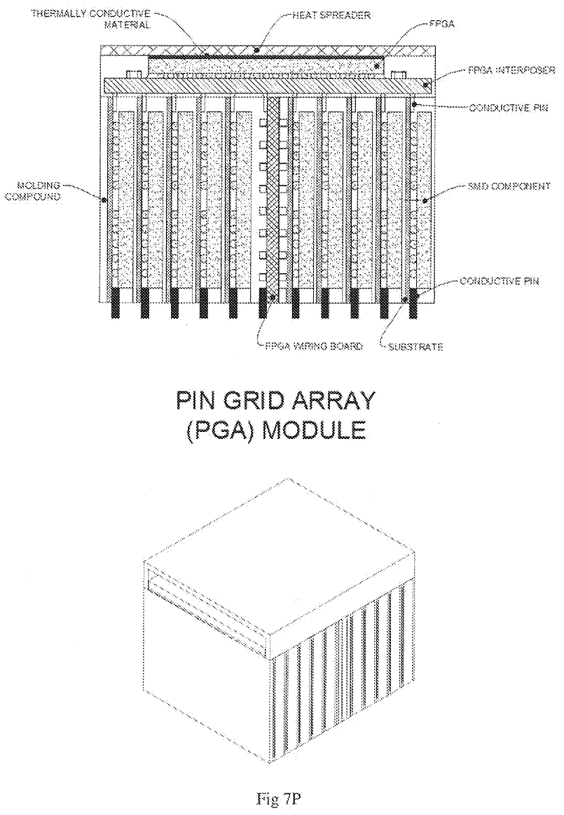

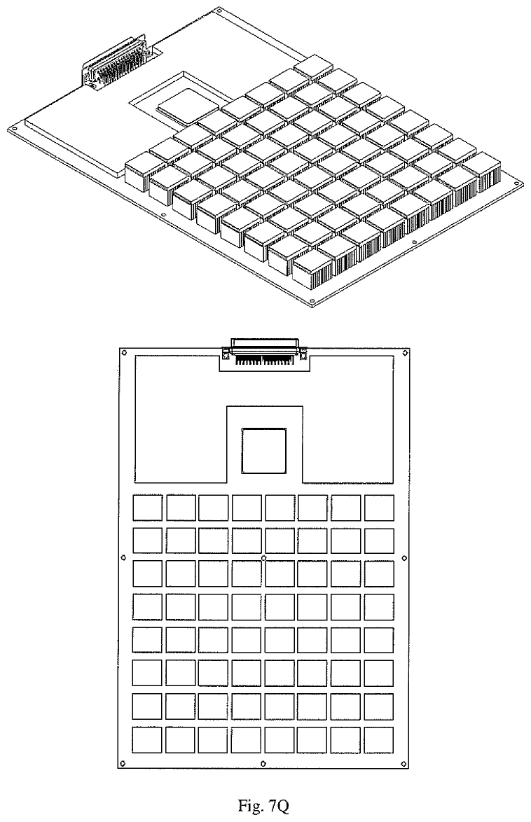

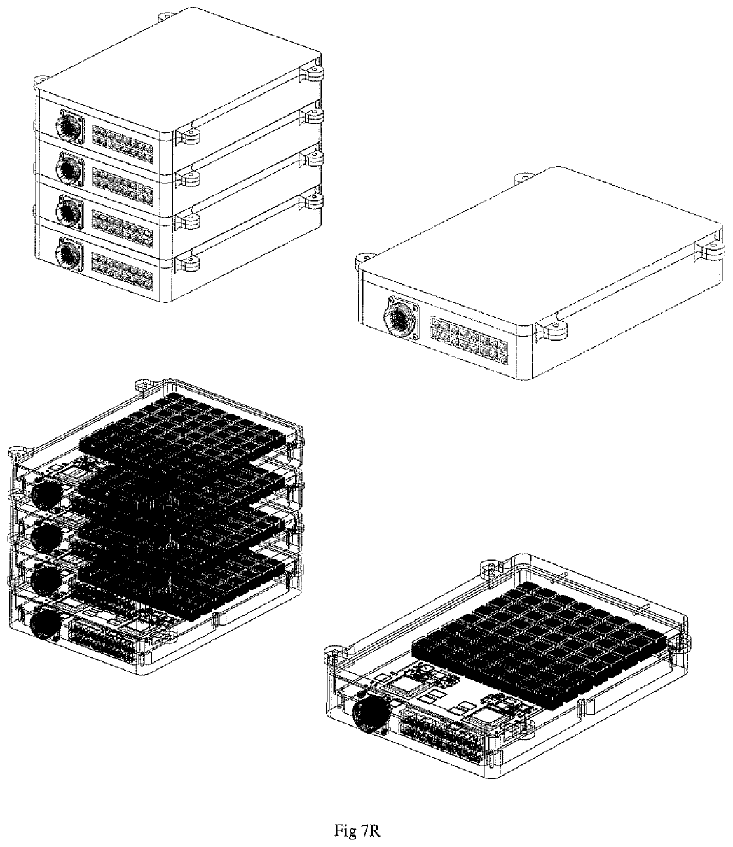

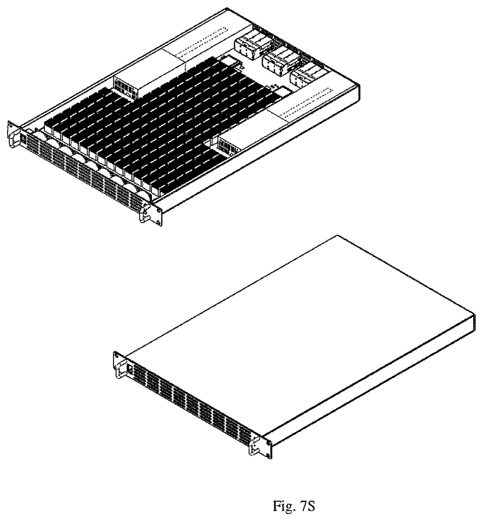

FIGS. 7A-7S depict a memory module of the disclosure throughout set of process steps for the fabrication of an embodiment of a memory module of the disclosure.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by any claims in any subsequent application claiming priority to this application.

For example, notwithstanding the fact that the elements of such a claim may be set forth in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus, if an element can be understood in the context of this specification as including more than one meaning, then its use in a subsequent claim must be understood as being generic to all possible meanings supported by the specification and by the word itself.

The definitions of the words or elements of any claims in any subsequent application claiming priority to this application should be, therefore, defined to include not only the combination of elements which are literally set forth, but all equivalent structure, material or acts for performing substantially the same function in substantially the same way to obtain substantially the same result. In this sense, it is therefore contemplated that an equivalent substitution of two or more elements may be made for any one of the elements in such claims below or that a single element may be substituted for two or more elements in such a claim.

Although elements may be described above as acting in certain combinations and even subsequently claimed as such, it is to be expressly understood that one or more elements from a claimed combination can in some cases be excised from the combination and that such claimed combination may be directed to a subcombination or variation of a subcombination.

Insubstantial changes from any subsequently claimed subject matter as viewed by a person with ordinary skill in the art, now known or later devised, are expressly contemplated as being equivalently within the scope of such claims. Therefore, obvious substitutions now or later known to one with ordinary skill in the art are defined to be within the scope of the defined elements.

Any claims in this or any subsequent application claiming priority to this application are thus to be understood to include what is specifically illustrated and described above, what is conceptually equivalent, what can be obviously substituted and also what essentially incorporates the essential idea of the invention.

1. A device comprising a plurality of packaged memory integrated circuits mounted to a substrate with integrated pins that are edge connected on two surfaces where the top surface provides an edge connection from the integrated circuits to an orthogonally mounted memory controller through a wide-word interface and configured where each integrated circuit can be accessed independently and wherein the memory controller reduces the wide-word interface to a serial interface which is routed to an opposite face for attachment to a system substrate.

2. A method of producing the device of claim 1 wherein the package substrate uses a lead frame that is soldered or welded to the substrate and each finger of the lead frame is used for aligning the layers to the required pitch to mount the controller as well as providing a means for compliance and flexibility in achieving said pitch.

3. A method using the lead frame of claim 2 wherein after the plurality of packages are stacked and the lead frame fingers are bent in a J-lead fashion to provide a planar surface for mounting the controller circuit.

4. A method of communication between cubes using the faces of the module in any direction independently to allow bypassing of routing signals out of the overall physical memory and back in.

5. A method of using the enclosure to help channel communication via waveguide (electrical, physical hollow waveguides, or optical) to create larger zones of memory for robotics, universities, and institutions dealing with massive data sets and data distributed applications.

6. A device of claim 1 wherein a visual indicator is placed on the top surface as to provide status of said device and to provide a means for identifying and replacing failed devices.

7. A device of claim 1 wherein the input/output interface uses pins or leads that can be inserted into receptacles on the host substrate allowing said device to be easily swapped.

8. The device of claim 7 wherein the receptacles have multiple contact surfaces such that removal of the devices closes a mechanical circuit allowing the daisy-chainable signal path to remain active such that said devices can be hot-swapped or removed without affecting the signal chain connectivity.

9. A plurality of devices of claim 1 wherein each daisy-chained serial interface of a group of devices contains a terminating circuit wherein each terminating circuit is connected to adjacent terminating circuits such that the terminating circuit can automatically connect the end of one serial chain to the end of another serial chain for the purpose of extending the serial chain in case of failure or breakage of one serial chain.

10. The device of claim 1 wherein point-of-load power regulation is performed to simplify power distribution of the host substrate.

11. A method using a plurality of the devices of claim 1 wherein a subset of said devices are grouped in a n-modular redundancy fashion wherein each device of said subset automatically transfers command or data to other devices in said subset such that said data can be stored in a redundant fashion without requiring specific intervention by the host processor and wherein devices of said group perform necessary voting of data from multiple devices such that the majority vote is returned to the host processor without requiring multiple read-back and voting by the host processor.

12. A method using a plurality of the devices of claim 1, referred to as a group, wherein a single device is used as a parity device which monitors the daisy-chained interface in a promiscuous mode such that every data transaction to any device within the chain is intercepted and exclusive-OR'd (XOR) with existing data within said parity module such that said parity module at all times contains the even or odd parity of said group allowing for reconstruction of data in the event of a failing device within said group.

13. A method using the devices of claim 1 wherein the logical to physical address translation is distributed between the host controller and the memory controller of said device such that the host controller is required to map only a subset of the addresses wherein the remaining address space is mapped by said memory controller.
